(19) United States
(12) Patent Application Publication
(10) Pub. No.: US 2022/0400580 A1
(43) Pub. Date: Dec. 15, 2022

(54) CIRCUIT ASSEMBLY

(71) Applicants: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(72) Inventors: Yuki FUJIMURA, Mie (JP); Hitoshi TAKEDA, Mie (JP)

(73) Assignees: AUTONETWORKS TECHNOLOGIES, LTD., Mie (JP); SUMITOMO WIRING SYSTEMS, LTD., Mie (JP); SUMITOMO ELECTRIC INDUSTRIES, LTD., Osaka (JP)

(21) Appl. No.: 17/779,074

(22) PCT Filed: Nov. 26, 2020
(86) PCT No.: PCT/JP2020/044063

§ 371 Date: May 23, 2022

(30) Foreign Application Priority Data
Dec. 4, 2019 (JP) 2019-219846

(51) Int. Cl. H05K 7/20

(52) U.S. Cl. CPC H05K 7/20272

(57) ABSTRACT

Disclosed is a circuit assembly having a novel structure capable of more reliably promoting heat dissipation from a heat generating component, using a short heat transfer path. A circuit assembly includes: a heat generating component that generates heat when energized; a conductive member configured to be connected to a connection portion of the heat generating component; and a cooling component configured to allow a coolant to flow therethrough and is in thermal contact with the conductive member.

### TECHNICAL FIELD

The present disclosure relates to a circuit assembly including a heat generating component.

### BACKGROUND ART

Conventionally, a circuit assembly including a heat generating component such as a relay is mounted in a vehicle. For example, Patent Document 1 describes a circuit assembly including a relay that interrupts supply of power from a battery to a motor or a generator that is connected, via an inverter, as a vehicle-side load.

A large current flows through a heat generating component, such as a relay, used in such a circuit assembly. Accordingly, the amount of Joule heat proportional to the square of the current amount is generated, and the amount of heat generated is also increased. For this reason, Patent Document 1 proposes a structure for dissipating heat from a relay by utilizing an intermediate portion of a bus bar, which is a conductive member that connects a connection portion of the relay accommodated in a case to a connection terminal of a battery disposed outside the case. Specifically, Patent Document 1 discloses a structure in which a relay is brought into contact with a chassis, a casing, or the like accommodating the entire power supply device via a heat transfer sheet at an intermediate portion of a bus bar that extends to the outside of a case accommodating the relay, thereby dissipating the heat generated in the relay to the chassis or the casing through thermal conduction.

### CITATION LIST

Patent Document
Patent Document 1: JP 2014-79093A

### SUMMARY OF INVENTION

### Technical Problem

Meanwhile, for a bus bar constituting a conductive member that connects a relay and a battery to each other, a large thickness or area needs to be ensured in order to withstand large currents. For this reason, a structure disclosed in Patent Document 1 is problematic in that a heat dissipation path needs to be additionally provided using a large bus bar, resulting in an increase in material and processing costs. In addition, the large bus bar needs to extend over a long distance to another heat dissipation member provided outside the case, and the distance between the connection portion of the relay and the heat dissipation portion is inevitably increased. Accordingly, the structure also has an inherent problem in that the heat generated in the relay is not efficiently dissipated.

Therefore, the present disclosure discloses a circuit assembly having a novel structure capable of more reliably promoting heat dissipation from a heat generating component, using a short heat transfer path.

### Solution to Problem

A circuit assembly according to the present disclosure is a circuit assembly including: a heat generating component that generates heat when energized; a conductive member configured to be connected to a connection portion of the heat generating component; and a cooling component configured to allow a coolant to flow therethrough and is in thermal contact with the conductive member.

### Advantageous Effects of Invention

According to the present disclosure, it is possible to more reliably promote heat dissipation from a heat generating component, using a short heat transfer path.

### BRIEF DESCRIPTION OF DRAWINGS

FIG. 1 is a perspective view of a circuit assembly according to Embodiment 1.

FIG. 2 is an exploded perspective view of the circuit assembly shown in FIG. 1.

FIG. 3 is a diagram schematically showing an electrical configuration in a path extending from a power supply to a load in the circuit assembly shown in FIG. 1.

FIG. 4 is an exploded perspective view of a base member that constitutes the circuit assembly shown in FIG. 1.

FIG. 5 is an exploded perspective view of cooling components that constitute the circuit assembly shown in FIG. 1.

FIG. 6 is an exploded perspective view showing the cooling components shown in FIG. 5 from a different direction.

FIG. 7 is a perspective view of a circuit assembly according to Embodiment 2.

FIG. 8 is a perspective view of a circuit assembly according to Embodiment 3.

FIG. 9 is a perspective view of a circuit assembly according to Embodiment 4.

### DESCRIPTION OF EMBODIMENTS

### Description of Embodiments of the Present Disclosure

First, aspects of the present disclosure will be listed and described.

A circuit assembly according to the present disclosure is

(1) a circuit assembly including: a heat generating component that generates heat when energized; a conductive member configured to be connected to a connection portion of the heat generating component; and a cooling component configured to allow a coolant to flow therethrough and is in thermal contact with the conductive member.

With the circuit assembly according to the present disclosure, the cooling component through which the coolant flows is in thermal contact with the conductive member that is directly connected to the connection portion that constitutes a heat generation portion of the heat generating component. Accordingly, the conductive member to which the heat from the heat generating component is transferred can be actively cooled by the cooling component, thus making it possible to more reliably promote heat dissipation from the heat generating component, using a shorter heat transfer path than that of a conventional structure, and to improve the heat dissipation performance of the circuit assembly.

In particular, since the conductive member to which the heat from the heat generating component is transferred is cooled by the coolant flowing through the cooling component, the heat dissipation effect and the cooling effect can be improved as compared with a conventional structure in which a chassis or a casing with which the conductive member such as a bus bar is in thermal contact reaches high temperatures exceeding 70° C.

As the coolant flowing through the coolant flow path, it is possible to use any coolant that can be used in a vehicle, such as radiator fluid. The mode of the thermal contact of the cooling component with the conductive member includes a mode in which the cooling component is brought into direct contact with the conductive member, and a mode in which the cooling component is brought into indirect contact with the conductive member via another member having high thermal conductivity. In addition, since the conductive member is connected to the connection portion of the heat generating component, the heat from the heat generating component is advantageously transferred to the conductive member. However, the conductive member connected to the connection portion of the heat generating component encompasses both a conductive member used for carrying current between the connection portion of the heat generating component and another member and a conductive member that is simply used for heat dissipation without being connected to another member. The heat generating component includes components that generate heat when energized, such as a relay and a fuse.

(2) It is preferable that the cooling component is fastened to the connection portion of the heat generating component via the conductive member. This is because the cooling component is fastened to the connection portion that constitutes a heat generation portion of the heat generating component, together with the conductive member, whereby the separation distance between the heat generating component and the heat dissipation portion can be substantially eliminated, thus making it possible to even more efficiently dissipate heat from the heat generating component.

(3) It is preferable that the cooling component includes a coolant flow path including a flow inlet and a flow outlet for the coolant, and is configured to allow an external coolant supply path and an external coolant discharge path to be connected to the flow inlet and the flow outlet. This is because an external coolant supply/discharge path can be easily connected to the flow inlet and the discharge outlet of the coolant flow path provided in the cooling component, thus making it possible to easily circulate the coolant inside the coolant flow path of the cooling component.

(4) It is preferable that, in (3) above, the cooling component includes an annular cylinder body, and an inner hole of the annular cylinder body serves as a fastening component insertion hole, the annular cylinder body includes an annular first part and an annular second part that are configured to be attached to each other in an axial direction thereof, the first part includes a recessed first flow passageway forming portion that is open to an attachment surface to the second part, and the second part includes a recessed second flow passageway forming portion that is open to an attachment surface to the first part, and as a result of the first part and the second part being attached and fixed to each other in a state in which the attachment surfaces are in close contact with each other via a sealing member, the coolant flow path defined by the first flow passageway forming portion and the second flow passageway forming portion is formed inside the annular cylinder body.

The fastening component insertion hole into which the fastening component can be inserted is formed using the inner hole of the annular cylinder body, and the cooling component capable of being fastened with the fastening component can be provided in a compact manner. Moreover, since the coolant flow path is defined by bringing the first flow passageway forming portion and the second flow passageway forming portion, which are open to the attachment surface of the annular first/second part, into close contact with each other via the sealing member, the cooling component can be formed using a simple mold structure.

(5) It is preferable that, in (4) above, one of the first part and the second part that comes into contact with the conductive member is formed of a material having higher thermal conductivity than a material that forms the other of the first part and the second part. This is because the heat transfer performance of the cooling component can be efficiently improved by improving the thermal conductivity of one of the parts that comes into contact with the conductive member, while suppressing the costs involved with the other part.

(6) It is preferable that the cooling component is fixed to the conductive member using a bolt so as to be in contact with the conductive member, and the cooling component includes a rotation blocking projection that abuts against another member to block rotation of the cooling component. Since excessive rotation of the cooling component can be blocked by the rotation blocking projection included in the cooling component abutting against another member, fastening through bolting between the cooling component and the conductive member can be performed advantageously.

### Details of Embodiments of the Present Disclosure

Specific examples of a circuit assembly according to the present disclosure will be described below with reference to the drawings. It should be noted that the present disclosure is not limited to these examples, but is defined by the claims, and is intended to include all modifications which fall within the scope of the claims and the meaning and scope of equivalents thereof.

### Embodiment 1

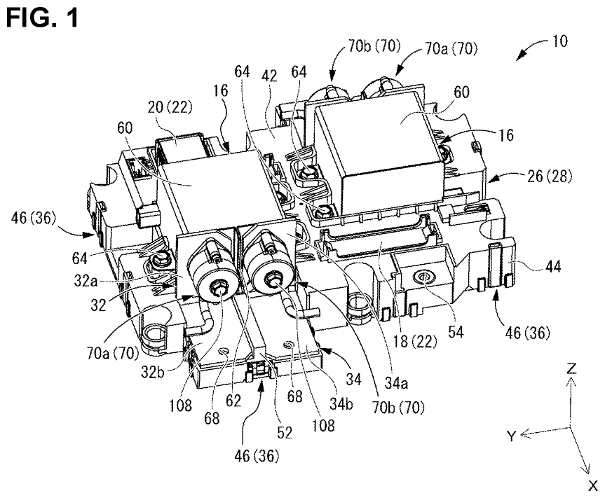

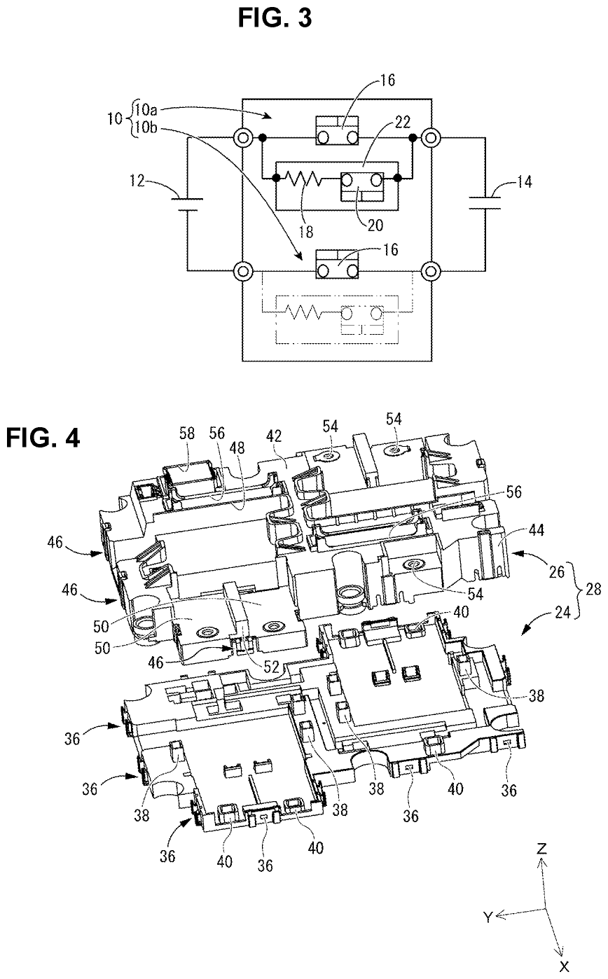

In the following, Embodiment 1 of the present disclosure will be described with reference to FIGS. 1 to 6. A circuit assembly 10 can be mounted in, for example, a vehicle (not shown) such as an electric automobile or a hybrid automobile, and enables supply and control of power from a power supply 12 such as a battery to a load 14 such as a motor (see FIG. 3). Although the orientation of the circuit assembly 10 mounted in the vehicle is not particularly limited, the following description will be given assuming that the upward direction is the Z direction in FIG. 1, the forward direction is the X direction in FIG. 1, and the leftward direction is the Y direction in FIG. 1. For a plurality of identical members, reference numerals may be assigned to some of the members, and reference numerals may be omitted for the other members.

### Schematic Circuit Configuration of Circuit Assembly 10

As shown in FIG. 3, the circuit assembly 10 includes a circuit assembly 10a provided on the positive electrode side, and a circuit assembly 10b provided on the negative electrode side. The positive electrode of the power supply 12 is connected to the input side of the circuit assembly 10a, and the negative electrode of the power supply 12 is connected to the input side of the circuit assembly 10b. The positive electrode of the load 14 is connected to the output side of the circuit assembly 10a, and the negative electrode of the load 14 is connected to the output side of the circuit assembly 10b. A relay 16 serving as a heat generating component that connects the power supply 12 to the load 14 is connected between the input side and the output side of each of the circuit assembly 10a and the circuit assembly 10b. In addition, a pre-charge circuit 22 including a pre-charge resistor 18 and a pre-charge relay 20 that are connected in series so as to bypass the relay 16 is connected to the relay 16 that connects the positive electrode sides of the power supply 12 and the load 14.

As shown in FIG. 3, in Embodiment 1 of the present disclosure, the pre-charge resistor 18 is connected to the input side of the pre-charge relay 20. Similarly, a pre-charge circuit 22 is also connected to the relay 16 that connects the negative electrode sides of the power supply 12 and the load 14. In FIG. 3, the pre-charge circuit 22 connected to the relay 16 that connects the negative electrodes of the power supply 12 and load 14 is indicated by the dashed double-dotted line. Both the relay 16 and the pre-charge relay 20 are a relay that switches a contact portion on and off by moving the contact portion while an exciting coil is energized, and is turned on or off by a control circuit (not shown). As described thus far, the circuit assembly 10a and the circuit assembly 10b have substantially the same structure.

### Circuit Assembly 10

For example, as shown in FIG. 4, the circuit assembly 10 includes a lower case 24 that is located on the lower side and an upper case 26 that is located on the upper side when mounted in a vehicle. The lower case 24 and the upper case 26 constitute an insulating base member 28. Bus bars that connect the relays 16 to the pre-charge circuits 22, and bus bars that connect the interior of the pre-charge circuits 22 are accommodated inside the base member 28. The base member 28 is provided with two relays 16, and bus bars 32 and 34 serving as conductive members respectively connected to connection portions 30a and 30b of each of the relays 16.

### Lower Case 24

The lower case 24 is formed by injection molding an insulating synthetic resin into a predetermined shape. The synthetic resin that forms the lower case 24 may contain a filler such as glass fiber. The lower case 24 has an overall horizontally elongated (the width in the left-right direction is larger than the width in the front-rear direction) flat shape. A plurality of lower engaging portions 36 are provided on an outer peripheral surface of the lower case 24. The lower engaging portions 36 are configured to engage with upper engaging portions 46, which will be described later, provided on an outer peripheral surface of the upper case 26 so as to fix the lower case 24 and the upper case 26 to each other. The mode of engagement between the lower engaging portions 36 and the upper engaging portions 46 is not limited, and projection/depression fitting or the like may be used, for example.

Relay fixing portions 38 having a substantially rectangular tube shape to which leg portions 63, which will be described later, of the relays 16 and 16 are configured to be bolted are provided protruding upward on an upper surface of the lower case 24. Additionally, bolt insertion portions 40 for connecting wires or the like to the relays 16, the pre-charge resistors 18, the pre-charge relays 20 and so forth are provided on the upper surface of the lower case 24. That is, wires and the relays 16 and so forth can be electrically connected to each other as a result of bolts being inserted into the bolt insertion portions 40 in a state in which terminal portions provided at ends of the wires are overlaid with the upper case 26. The lower case 24 includes a plurality of bolt insertion portions 40 having a substantially rectangular tube shape.

### Upper Case 26

The upper case 26 is formed by injection molding an insulating synthetic resin into a predetermined shape. The synthetic resin that forms the upper case 26 may contain a filler such as glass fiber. The upper case 26 has an overall substantially box-like shape that is open downward, and includes an upper wall 42 having substantially the same shape as the lower case 24, and a peripheral wall 44 protruding downward from the upper wall 42. Upper engaging portions 46 are provided at a lower end of the peripheral wall 44 at locations corresponding to the lower engaging portions 36 of the lower case 24, and the upper engaging portions 46 are configured to be engageable with the lower engaging portions 36.

Accommodating recesses 48 in which the relays 16 are to be accommodated are formed in the upper case 26. In Embodiment 1, an accommodating recess 48 in which the relay 16 on the positive electrode side is to be accommodated, and an accommodating recess 48 in which the relay 16 on the negative electrode side is to be accommodated are provided spaced apart from each other in the left-right direction. The bottom surface of each accommodating recess 48 is formed as a substantially flat surface extending on a horizontal plane (plane extending in a direction orthogonal to the up-down direction), and is provided at a position lower than the upper wall 42. Additionally, placement surfaces 50 and 50 on which the bus bars 32 and 34 are to be placed are provided forward of the left accommodating recess 48 and rearward of the right accommodating recess 48. The placement surfaces 50 and 50 are provided at a position lower than the bottom surface of the corresponding accommodating recess 48. A partition wall portion 52 protruding in the up-down direction is provided between the placement surfaces 50 and 50. This can prevent electrical shorting caused as a result of the bus bar 32 connected to the positive side of the relay 16 and the bus bar 34 connected to the negative side thereof coming into contact each other.

The upper wall 42 has through holes 54 extending therethrough in the up-down direction at positions corresponding to the relay fixing portions 38 and the bolt insertion portions 40 of the lower case 24. By inserting bolts into the through holes 54, it is possible to fasten the relays 16 through bolting, and electrically connect wires or the like to the bus bars 32 and 34. In addition, pre-charge resistor attachment portions 56 for attaching the pre-charge resistors 18, and pre-charge relay attachment portions 58 for attaching the pre-charge relays 20 are provided on the upper wall 42 so as to be open upward.

### Relay 16

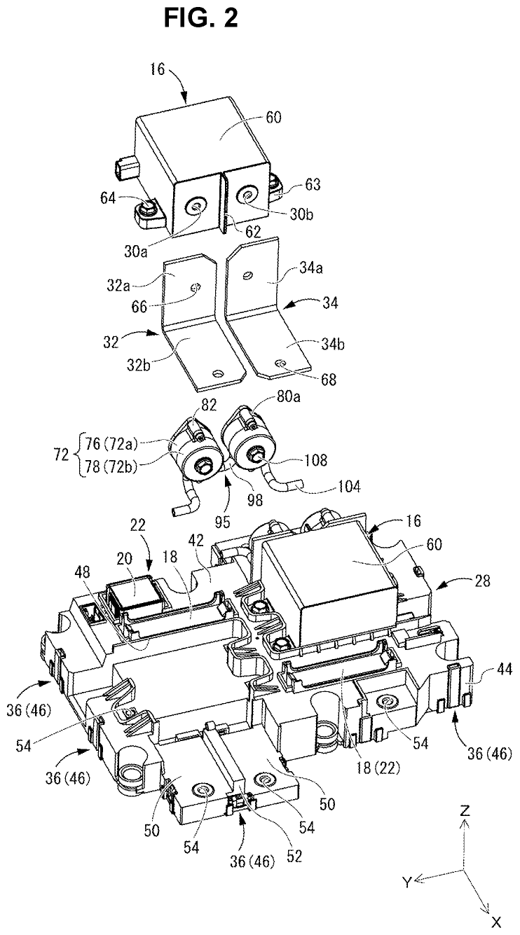

The relays 16 are mechanical relays, and are turned on or off by a control circuit (not shown). As also shown in FIG. 2, the relays 16 each have a relay body 60 having an overall substantially hollow rectangular parallelepiped shape, and include a contact portion and a coil portion, which are not shown, inside the relay body 60. Note that the left relay 16 and the right relay 16 have the same structure, and are attached so as to be inverted relative to each other in the front-rear direction. In the following description, the left relay 16 will be described, and description of the right relay 16 has been omitted. A pair of through holes are formed in a front end face of the relay body 60 so as to be spaced apart from each other in the left-right direction, and these through holes constitute the above-described connection portions 30a and 30b of the relay 16.

As a result of current flowing between the connection portions 30a and 30b via the contact portion of the relay 16 during energization, heat is generated in the contact portion. A partition plate portion 62 that protrudes forward is provided between the connection portions 30a and 30b so as to extend over substantially the entire length of the relay body 60 in the up-down direction. This prevents electrical shorting caused by contact between the bus bar 32 connected to the connection portion 30a on the positive side and the bus bar 34 connected to the connection portion 30b on the negative side.

The relay body 60 includes a plurality (three in the present embodiment) of leg portions 63 protruding therefrom toward opposite sides in the left-right direction, and a bolt insertion hole is formed in each of the leg portions 63. The relay 16 is attached to the base member 28 by inserting fixing bolts 64 into the through holes 54 formed in the bottom surface of the accommodating recess 48 of the base member 28 and the bolt insertion holes of the leg portions 63 in a state in which the through holes 54 and the bolt insertion holes are aligned with each other, and fastening the fixing bolts 64.

### Bus Bars 32 and 34

Each of the two bus bars 32 and 34 is formed by machining a conductive metal plate material. As also shown in FIG. 2, the bus bars 32 and 34 are formed so as to be bent in a substantially L-shape. Portions located on one side relative to the bent portions serve as substantially rectangular plate-shaped, first connection portions 32a and 34a that are configured to be connected to the connection portions 30a and 30b of the relay 16. The first connection portions 32a and 34a each have a bolt insertion hole 66 extending therethrough in the front-rear direction, which is the plate thickness direction. The bus bars 32 and 34 are configured to be electrically and thermally connected to the connection portions 30a and 30b of the relay 16 by being bolted to the connection portions 30a and 30b of the relay 16.

Portions of the bus bars 32 and 34 that are located on the other side relative to the bent portion extend forward, and the extending portions serve as substantially rectangular plate-shaped, second connection portions 32b and 34b. The second connection portions 32b and 34b each have a bolt insertion hole 68 extending therethrough in the up-down direction, which is the plate thickness direction. The bolt insertion holes 68 are configured to be aligned with the through holes 54 formed in the placement surfaces 50 and 50 of the base member 28 when the bus bars 32 and 34 are placed on the placement surfaces 50. Also, wires and the bus bars 32 and 34 are electrically connected to each other by inserting bolts into the bolt insertion holes 68 and the through holes 54, with terminal portions or the like provided at wire ends, which are not shown, being overlaid with the second connection portions 32b and 34b of the bus bars 32 and 34, and fastening the bolts.

### Cooling Component 70

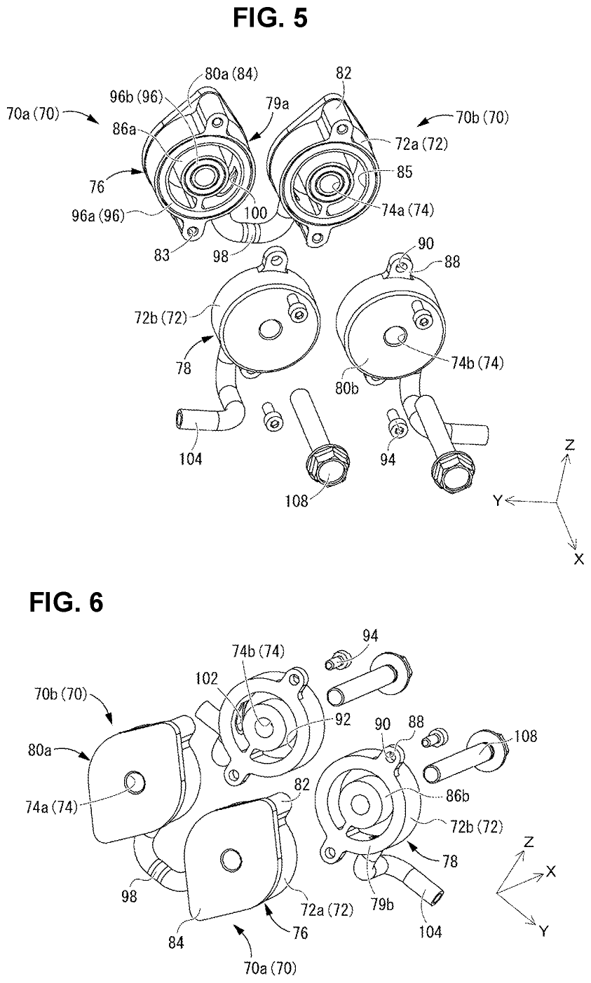

Cooling components 70 as shown in FIGS. 5 and 6 are in thermal contact with the bus bars 32 and 34. The cooling components 70 of Embodiment 1 each have an overall cylindrical shape extending in the front-rear direction, and include an annular cylinder body 72, and an inner hole 74 extending therethrough in the front-rear direction on the inner circumference side of the annular cylinder body 72.

In Embodiment 1, a pair of cooling components 70 and 70 are provided. That is, a first cooling component 70a is attached to the connection portion 30a on the positive side of the relay 16, and a second cooling component 70b is attached to the connection portion 30b on the negative side of the relay 16. In Embodiment 1, the first cooling component 70a and the second cooling component 70b have the same structure. Accordingly, in the following description, the first cooling component 70a will be described, and description of the second cooling component 70b has been omitted.

The annular cylinder body 72 of the first cooling component 70a includes a first part 76 and a second part 78 that are configured to be coupled to each other in the front-rear direction (central axis direction of the annular cylinder body 72). In Embodiment 1, the first part 76 and the second part 78 are attached to each other such that end faces thereof are overlaid with each other in the front-rear direction. That is, a front end face of the first part 76 serves as an attachment surface 79a to the second part 78, and a rear end face of the second part 78 serves as an attachment surface 79b to the first part 76. Accordingly, the annular cylinder body 72 and the inner hole 74 are configured to be separable in the front-rear direction, and the first part 76 includes a first annular cylinder body 72a and a first inner hole 74a that constitute a rear portion of the annular cylinder body 72 and the inner hole 74. The second part 78 includes a second annular cylinder body 72b and a second inner hole 74b that constitute a front portion of the annular cylinder body 72 and the inner hole 74.

The first part 76 has an overall substantially bottomed cylindrical shape, and the first annular cylinder body 72a protrudes forward from a first bottom wall portion 80a having a substantially disk-like shape. In Embodiment 1, protrusions 82 and 82 protruding toward opposite sides in the up-down direction are formed in one piece with the first annular cylinder body 72a. The protrusions 82 each have a semicircular or circular cross section, and extend over substantially the entire length of the first part 76 in the front-rear direction. Also, outer circumferential surfaces of the protrusions 82 and a portion of an outer circumferential surface of the first part 76 on which the protrusions 82 are not formed extend continuously on a smooth curved surface. A bolt opening 83 that is open forward is formed in each of the protrusions 82. The shape of the first bottom wall portion 80a substantially conforms to the shape of the first annular cylinder body 72a, and has a width in the up-down direction that is larger than the width in the left-right direction, and protruding portions 84 and 84 are formed on opposite sides of the first bottom wall portion 80a in the up-down direction.

Additionally, the first part 76 has, in a radially intermediate portion thereof, a recessed portion that is open to the front end face (attachment surface 79a) thereof. In Embodiment 1, the recessed portion serves as a circumferentially extending arc-shaped recess 85. In particular, in Embodiment 1, the arc-shaped recess 85 extends with a circumferential dimension of approximately one rotation. That is, in Embodiment 1, a first inner cylinder portion 86a is provided on the inner circumference side of the first annular cylinder body 72a so as to be spaced apart radially therefrom. The first inner hole 74a is formed on the inner circumference side of the first inner cylinder portion 86a, and the arc-shaped recess 85 is formed radially between the first annular cylinder body 72a and the first inner cylinder portion 86a.

The first part 76 has a double cylinder structure composed of the first annular cylinder body 72a and the first inner cylinder portion 86a, and the first annular cylinder body 72a and the first inner cylinder portion 86a are coupled to each other by a portion on the circumference of the first part 76. Accordingly, when a coolant, which will be described later, flows through the first and second cooling components 70a and 70b, the coolant can flow around inside the first and second cooling components 70a and 70b. Therefore, a sufficient length for a a coolant flow path 95, which will be described later, can be secured, and the cooling effect can be stably achieved.

The second part 78 has an overall substantially bottomed cylindrical shape, and the second annular cylinder body 72b protrudes rearward from a second bottom wall portion 80b having a substantially disk-like shape. Protrusions 88 protruding toward opposite sides in the up-down direction are formed in one piece with the second annular cylinder body 72b. The protrusions 88 have the same outer shape as that of the protrusions 82 of the first part 76. The protrusions 88 do not extend over the entire length of the second part 78 in the front-rear direction, and are provided at a rear end portion of the second part 78. Also, a bolt hole 90 is formed so as to extend through each of the protrusions 88 in the front-rear direction.

The second part 78 has, in a radially intermediate portion thereof, a recessed portion that is open to the rear end face (attachment surface 79b) thereof. In Embodiment 1, the recessed portion serves as a circumferentially extending arc-shaped recess 92. In particular, in Embodiment 1, the arc-shaped recess 92 extends with a circumferential dimension of approximately one rotation. That is, in Embodiment 1, a second inner cylinder portion 86b is provided on the inner circumference side of the second annular cylinder body 72b so as to be spaced apart radially therefrom. The second inner hole 74b is formed on the inner circumference side of the second inner cylinder portion 86b, and the arc-shaped recess 92 is formed radially between the second annular cylinder body 72b and the second inner cylinder portion 86b.

The second part 78 has a double cylinder structure composed of the second annular cylinder body 72b and the second inner cylinder portion 86b, and the second annular cylinder body 72b and the second inner cylinder portion 86b are coupled to each other by a portion on the circumference of the second part 78. Accordingly, when a coolant, which will be described later, flows through the first and second cooling components 70a and 70b, the coolant can flow around inside the first and second cooling components 70a and 70b. Therefore, a sufficient length for the coolant flow path 95, which will be described later, can be secured, and the cooling effect can be stably achieved.

Also, by overlaying the attachment surface 79a of the first part 76 and the attachment surface 79b of the second part 78 with each other, the protrusions 82 of the first part 76 and the protrusions 88 of the second part 78 are also overlaid with each other, whereby the bolt holes 83 and the bolt holes 90 are in communication with each other. By inserting and fastening fixing bolts 94 to the bolt holes 83 and the bolt holes 90 from the front side, the first part 76 and the second part 78 are coupled to each other in the front-rear direction. Consequently, the first annular cylinder body 72a and the second annular cylinder body 72b extend continuously to form the annular cylinder body 72, and the first inner hole 74a and the second inner hole 74b are in communication with each other to form the inner hole 74. In addition, the arc-shaped recess 85 of the first part 76 and the arc-shaped recess 92 of the second part 78 are in communication with each other in the front-rear direction. Also, an area defined by the two arc-shaped recesses 85 and 92 serves as the coolant flow path 95 through which the coolant flows. Note that, as the coolant that flows through the coolant flow path 95, it is possible to use any coolant that can be used in a vehicle, such as radiator fluid.

That is, in Embodiment 1, the rear end faces of the first annular cylinder body 72a and the first inner cylinder portion 86a are overlaid with the front end faces of the second annular cylinder body 72b and the second inner cylinder portion 86b. O-rings 96 serving as sealing members are provided between the overlaid faces. In short, an outer circumferential O-ring 96a is provided between the first and second annular cylinder bodies 72a and 72b, and an inner circumferential O-ring 96b is provided between the first inner cylinder portion 86a and the second inner cylinder portion 86b. As a result of the outer and inner O-rings 96a and 96b being compressed in the front-rear direction when the first part 76 and the second part 78 are attached to each other, the attachment surfaces 79a and 79b of the first part 76 and the second part 78 come into close contact with each other, thus preventing the coolant from leaking.

One first cooling component 70a and one second cooling component 70b having the above-described structure are provided on the left and right sides, respectively, of each relay 16. Also, the first cooling component 70a and the second cooling component 70b that are adjacent to each other are brought into communication with each other in the left-right direction via a tube 98. In Embodiment 1, a through hole 100 is formed in each of the two first annular cylinder bodies 72a and 72a that are adjacent to each other in the left-right direction so as to extend therethrough in the thickness direction. As a result of the tube 98 being fixed to the respective opening edges of the through holes 100 through bonding, welding, or the like, the arc-shaped recesses 85 and 85 (i.e., the coolant flow paths 95 and 95) are brought into communication with each other via the tube 98.

A through hole 102 is formed in each of the two second annular cylinder bodies 72b and 72b that are adjacent to each other in the left-right direction so as to extend therethrough in the thickness direction. As a result of an outwardly extending tube 104 being fixed to an opening edge of each of the through holes 102 through bonding, welding, or the like, each of the two arc-shaped recesses 92 and 92 (i.e., the two coolant flow paths 95 and 95) is brought into communication with an external space via the tube 104.

Accordingly, one through hole 102 serves as a flow inlet of the coolant to the coolant flow path 95, and the other through hole 102 serves as a flow outlet for the coolant from the coolant flow path 95.

Also, the tube 104 connected to the one through hole 102 (flow inlet) serves as a coolant supply path for supplying the coolant to the coolant flow path 95 from the outside. Similarly, the tube 104 connected to the other through hole 102 (flow outlet) serves as a coolant discharge path for discharging the coolant from the coolant flow path 95 to the outside. A first flow passageway forming portion that is open in the first part 76 to the attachment surface 79a to the second part 78, and that forms a portion of the coolant flow path 95 is formed by the arc-shaped recess 85. Similarly, a second flow passageway forming portion that is open in the second part 78 to the attachment surface 79b to the first part 76, and that forms a portion of the coolant flow path 95 is formed by the arc-shaped recess 92.

The cooling components (the first part 76 and the second part 78) described above can be suitably made of a hard synthetic resin, for example. One (the first part 76 in Embodiment 1) of the first part 76 and the second part 78 that comes into contact with the bus bars 32 and 34 serving as the conductive members is preferably made of a material having high thermal conductivity.

### Process of Assembling Circuit Assembly 10

Next, an example of the process of assembling the circuit assembly 10 will be described. The process of assembling the circuit assembly 10 is not limited to the following description.

First, the lower case 24 and the upper case 26 that constitute the base member 28 are prepared. Next, the bus bars that connect the relays 16 to the pre-charge circuits 22, and the bus bars that connect the interior of the pre-charge circuits 22 are disposed and accommodated in the lower case 24 or the upper case 26. Subsequently, the upper case 26 is overlaid with the lower case 24 from above so as to engage the lower engaging portions 36 with the upper engaging portions 46. Consequently, the lower case 24 and the upper case 26 are attached to each other, thus forming a base member 28.

Then, the relays 16 are disposed in the accommodating recesses 48 of the upper case 26, and the relays 16 are fixed to the base member 28 using the fixing bolts 64. Subsequently, the bus bars 32 and 34 are disposed on each of the two relays 16. In the following description, the left relay 16 will be described

That is, the first connection portions 32a and 34a of the bus bars 32 and 34 are overlaid with the connection portions 30a and 30b of the relay 16 from the front side. Also, the second connection portions 32b and 34b of the bus bars 32 and 34 are overlaid, from above, with the placement surfaces 50 located on the front side relative to a bottom surface of the accommodating recess 48.

Next, pre-assembled cooling components 70 (first and second cooling components 70a and 70b) are overlaid with a front end face of the relay 16 via the first connection portions 32a and 34a of the bus bars 32 and 34. Then, the connection portions 30a and 30b of the relay 16, the respective corresponding bolt insertion holes 66 and 66 of the first connection portions 32a and 34a, and the respective corresponding inner holes 74 (first and second inner holes 74a and 74b) of the first and second cooling components 70a and 70b are aligned with each other. The fixing bolts 108 and 108 serving as fastening components are inserted into and fastened to the connection portions 30a and 30b, the bolt insertion holes 66 and 66, and the inner holes 74a and 74b. Consequently, the first and second cooling components 70a and 70b are fixed through bolting to the connection portions 30a and 30b of the relay 16 via the bus bars 32 and 34. In other words, the first and second cooling components 70a and 70b are fastened together, using the fixing bolts 108 and 108 for fixing the bus bars 32 and 34 to the relay 16. That is, fastening component insertion holes into which the fixing bolts 108 serving as the fastening components are inserted are formed in the cooling component 70 by the inner holes 74 of the annular cylinder body 72.

Accordingly, the first and second bottom wall portions 80a and 80b of the first and second cooling components 70a and 70b come into thermal contact with the bus bars 32 and 34 by coming into direct contact therewith. In particular, the first and second bottom wall portions 80a and 80b include the protruding portions 84 and 84 protruding toward opposite sides in the up-down direction, and a large contact area with the bus bars 32 and 34 is secured. As a result, the efficiency with which heat is transferred from the bus bars 32 and 34 to the first and second cooling components 70a and 70b is improved. However, the bus bars 32 and 34 and the first and second cooling components 70a and 70b only need to be in thermal contact with each other, and need not be in direct contact with each other. That is, a member having heat transferring properties may be provided between each bus bar and the corresponding cooling component, or each bus bar and the cooling component may be in indirect contact with each other via a member having heat transferring properties.

When fastening the fixing bolts 108, the protrusions 82 and 88 and the protruding portions 84 in the up-down direction of the first and second cooling components 70a and 70b can be in contact with the partition plate portion 62 provided between the connection portions 30a and 30b of the relay 16. This can prevent the first and second cooling components 70a and 70b from rotating together with the fixing bolts 108 and 108. Accordingly, in Embodiment 1, the rotation blocking projection that blocks rotation of the cooling component 70 by abutting against another member is formed by at least one of the protrusion 82, the protrusion 88, and the protruding portion 84 in the cooling component 70.

The circuit assembly 10 is assembled through the above-described process. Power can be supplied to the relay 16 via the bus bars 32 and 34 as a result of terminal portions provided at wire ends being overlaid with and fixed through bolting to the second connection portions 32b and 34b of the bus bars 32 and 34.

In the circuit assembly 10 according to Embodiment 1 having the above-described structure, a contact portion inside each relay 16 generates heat as a result of power being supplied to the relay 16, and the heat is exerted on the bus bars 32 and 34 connected to the relay 16. In this respect, the cooling components 70 (first and second cooling components 70a and 70b) are in thermal contact with the bus bars 32 and 34, and a coolant flow path 95 through which a coolant flows is formed inside each of the cooling components 70. Accordingly, as a result of the coolant flowing through the coolant flow paths 95, the bus bars 32 and 34 are efficiently cooled, thus eliminating the heat generated from the relay 16. As a result, there is no need to separately provide a heat dissipating path or the like, and it is possible to dissipate heat from the heat generating components without an increase in the material and processing costs.

In the circuit assembly 10 of Embodiment 1, the first and second cooling components 70a and 70b are fastened, through fixation through bolting, to the relay 16 together with the bus bars 32 and 34. Therefore, means for fixing the heat generating components to the conductive members, and means for fixing the conductive members to the cooling components need not be provided separately, thus making it possible to simplify the structure of the circuit assembly 10. In particular, since the fixing bolts 108 and 108, which are directly fixed to the relay 16, serve as heat dissipation portions, it is possible to even more efficiently dissipate heat from the relay 16.

Furthermore, in the circuit assembly 10 of Embodiment 1, the tubes 104 are connected to the flow inlets (through holes 102) and the flow outlets (through holes 102) for the coolant of the first and second cooling components 70a and 70b, and form a coolant supply path and a coolant discharge path. This makes it possible to more reliably supply the coolant to the coolant flow path 95 from an external coolant source, and discharge the coolant to the external coolant source from the coolant flow path 95.

In particular, in the circuit assembly 10 of Embodiment 1, the first and second cooling components 70a and 70b each include an annular cylinder body 72 having an inner hole 74 that can be used as a fastening component insertion hole, and the annular cylinder body 72 is formed by attaching together a first part 76 and a second part 78 that are separate parts. Also, the coolant flow path 95 is formed so as to include a first flow passageway forming portion (arc-shaped recess 85) formed inside the first part 76 and a second flow passageway forming portion (arc-shaped recess 92) formed inside the second part 78. Accordingly, the first and second cooling components 70a and 70b capable of being fastened using fastening members and having a coolant flow path 95 thereinside can be formed using a mold with a simple structure. Since O-rings 96 (outer circumferential O-ring 96a and inner circumferential O-ring 96b) serving as sealing members are provided between the attachment surfaces 79a and 79b of the first part 76 and the second part 78, it is also possible to prevent the coolant from leaking from a space between the attachment surfaces 79a and 79b. Additionally, since the inner holes 74 of the annular cylinder bodies 72 are used as fastening component insertion holes into which the fixing bolts 108 serving as the fastening components are inserted, the cooling components 70 capable of being fastened using the fastening components can be provided in a compact manner.

Furthermore, of the first part 76 and the second part 78, the first part 76 that comes into contact with the bus bars 32 and 34 is preferably made of a material having high thermal conductivity. Accordingly, the heat generated by the relay 16 is more efficiently exerted on the first part 76 that forms the cooling component 70 via the bus bars 32 and 34, and cooling with the cooling component 70 can be more reliably achieved.

Furthermore, the first and second cooling components 70a and 70b each include the protrusions 82 and 88 and the protruding portions 84 that protrude toward opposite sides in the up-down direction, and are longer in the up-down direction than they are in the left-right direction. Accordingly, when the fixing bolts 108 and 108 are inserted into and fastened to the first and second cooling components 70a and 70b, portions of each of the first and second cooling components 70a and 70b that are located on opposite sides in the up-down direction come into contact with the partition plate portion 62, whereby the first and second cooling components 70a and 70b can be prevented from excessively rotating together with the fixing bolts 108 and 108.

### Embodiment 2

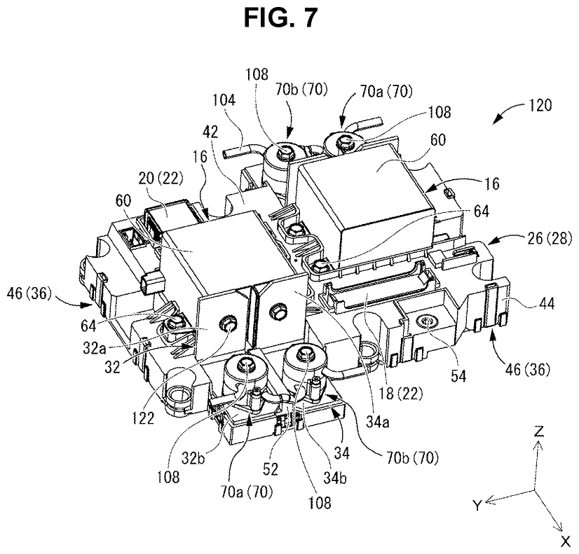

Next, Embodiment 2 of the present disclosure will be described with reference to FIG. 7. A circuit assembly 120 shown in FIG. 7 has the same overall structure as that of the circuit assembly 10 of the Embodiment 1, but differs in the positions at which the cooling components 70 (first cooling component 70a and second cooling component 70b) are attached. In the following description, the differences from the circuit assembly 10 of Embodiment 1 will be described, and descriptions of the portions having the same structure have been omitted. In the following description, members or portions that are substantially the same as those in Embodiment 1 are denoted by the same reference numerals as Embodiment 1 in the drawings, and descriptions thereof have been omitted.

In Embodiment 2, the first and second cooling components 70a and 70b are attached to the second connection portions 32b and 34b of the bus bars 32 and 34. That is, the through holes 54 formed in the placement surfaces 50 of the base member 28, the respective corresponding bolt insertion holes 68 formed in the second connection portions 32b and 34b, and the respective corresponding first and second inner holes 74a and 74b of the first and second cooling components 70a and 70b are aligned with each other. Between the second connection portions 32b and 34b and the first and second cooling components 70a and 70b, terminal portions provided at wire ends, which are not shown, are interposed in alignment with the bolt insertion holes. Also, the fixing bolts 108 and 108 are inserted into and fastened to the through holes 54, the bolt insertion holes 68, and the first and second inner holes 74a and 74b.

Terminal portions provided at wire ends, which are not shown, are overlaid with the first connection portions 32a and 34a of the bus bars 32 and 34, and are aligned with the bolt insertion holes 66 and 66 of the first connection portions 32a and 34a, and the connection portions 30a and 30b of each of the relays 16. Also, bolts 122 and 122 are inserted through and fastened to these components.

In the circuit assembly 120 of Embodiment 2 having the above-described structure, heat from the relay 16 can also be conducted to the bus bars 32 and 34, and be dissipated by the cooling components 70 that are in thermal contact with the bus bars 32 and 34. In particular, in Embodiment 2, the first and second cooling components 70a and 70b are fastened to the base member 28 together with the bus bars 32 and 34, and assembling can be efficiently performed as in Embodiment 1.

In Embodiment 2, a partition wall portion 52 included in the base member 28 is located between the first and second cooling components 70a and 70b. Accordingly, when the first and second cooling components 70a and 70b rotate, the protrusions 82 and 88 and the protruding portions 84 that protrude from the first and second cooling components 70a and 70b toward opposite sides in the front-rear direction abut against the partition wall portion 52, and block further rotation of the first and second cooling components 70a and 70b. Therefore, in Embodiment 2 as well, the rotation blocking projection that blocks rotation of the first and second cooling components 70a and 70b can be formed by at least one of the protrusion 82, the protrusion 88, and the protruding portion 84.

### Embodiment 3

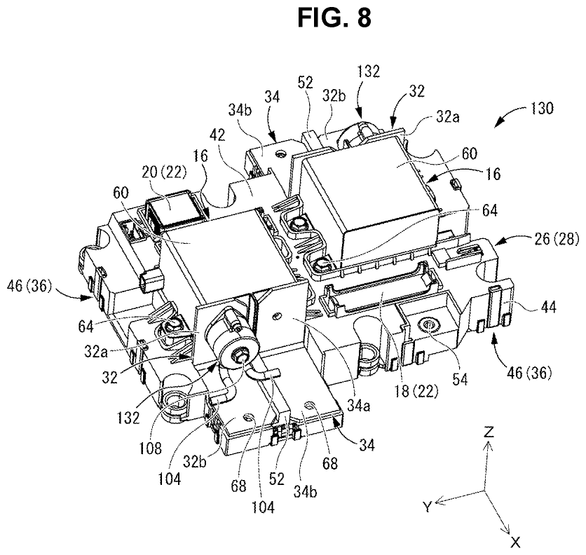

Next, Embodiment 3 of the present disclosure will be described with reference to FIG. 8. A circuit assembly 130 shown in FIG. 8 has the same overall structure as that of the circuit assembly 10 of the Embodiment 1, but differs from the circuit assembly 10 of the Embodiment 1 with regard to the structure of cooling components 132. In the following description, the differences from the circuit assembly 10 of Embodiment 1 will be described, and descriptions of the portions having the same structure have been omitted.

That is, in the circuit assembly 130 of Embodiment 3, each cooling component 132 is in thermal contact with one (bus bar 32) of the bus bars 32 and 34 connected to the connection portions 30a and 30b of the corresponding relay 16. In the circuit assembly 130 having such a structure, the cooling effect for the heat generated from the relay 16 can also be achieved. Each cooling component 132 of Embodiment 3 is also formed by a first part 76 and a second part 78 and has two through holes 102 and 102 formed in the second part 78, and tubes 104 and 104 that constitute a coolant supply path and a coolant discharge path can be connected to the through holes 102 and 102. Accordingly, the cooling component 132 of Embodiment 3 has a configuration in which the tube (98) that couples the first parts (76, 76) that are adjacent to each other in the left-right direction is not provided.

Although the circuit assembly 130 of Embodiment 3 includes two relays 16, and each relay 16 is provided with a cooling component 132, only one of the relays 16 may be provided with a cooling component 132. The cooling component need not be provided for the other bus bar 34 connected to the relay 16, or any conventionally known cooling component may be used.

### Embodiment 4

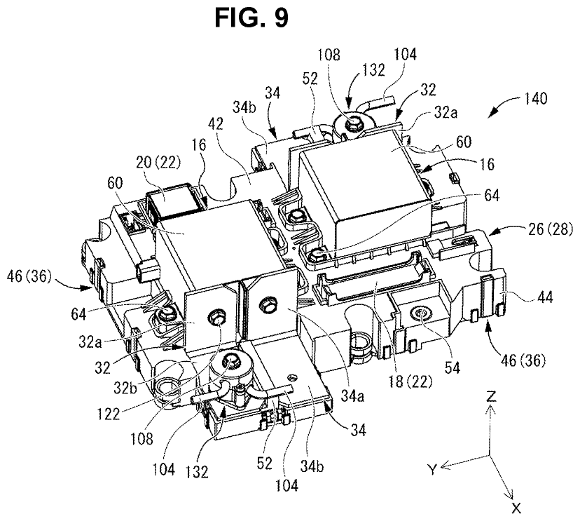

Next, Embodiment 4 of the present disclosure will be described with reference to FIG. 9. A circuit assembly 140 shown in FIG. 9 has the same overall structure as that of the circuit assembly 130 of Embodiment 3. However, as in the case of the circuit assembly 120 of Embodiment 2, each cooling component 132 is in thermal contact with the second connection portion 32b of the bus bar 32.

In the circuit assembly 140 having the above-described structure, the same effect as that of Embodiment 1 can also be achieved.

A configuration as shown in FIG. 8 in which each cooling component is brought into thermal contact with the first connection portion of a bus bar, and a configuration as shown in FIG. 9 in which each cooling component is brought into thermal contact with the second connection portion of a bus bar may be used in combination. That is, a cooling component 132 may be brought into thermal contact with the first connection portion 32a of one bus bar 32, while bringing another cooling component 132 into thermal contact with the second connection portion 34b of the other bus bar 34. In that case, the cooling components 132 and 132 may be coupled to each other with the tube 98 so as to form one coolant flow path, or may be independent of each other and respectively form separate coolant flow paths.

### Other Embodiments

The technique described in the present specification is not limited to the embodiments described and illustrated above. For example, the following embodiments also fall within the technical scope of the technique described in the present specification.

(1) In Embodiment 1 and Embodiment 2, cooling components having the same structure are used as the cooling components that are adjacent to each other in the left-right direction. However, the cooling components may differ from each other in shape, size, and so forth.

(2) In Embodiment 1 and Embodiment 2, the first parts 76 and 76 of the adjacent cooling components 70a and 70b are connected to each other by the tube 98, and the second parts 78 and 78 are connected to an external member via the respective tubes 104. The present disclosure is not limited to such a configuration, and the second parts may be connected to each other by a tube, and the first parts may be connected to an external member via tubes. Alternatively, the first part and the second part may be connected to each other with a tube.

(3) In the above-described embodiments, the arc-shaped recess 85 of the first part 76 and the arc-shaped recess 92 of the second part 78 have approximately the same circumferential length, and are provided at positions corresponding to each other. The present disclosure is not limited to such a configuration. For example, the arc-shaped recess 85 and the arc-shaped recess 92 may have circumferential lengths that are different from each other, or may be formed at circumferential positions that are different from each other, as long as circumferential recesses that are formed in the first part and the second part are in communication with each other when the two parts are attached to each other. However, the circumferential recesses need not be formed in both the first part and the second part, and an opening of a circumferential recess formed in one of the parts may be covered by the other part.

(4) In the above-described embodiments, the cooling components 70 and 132 each include a body portion having an overall cylindrical shape, but may have a body portion having a rectangular tube shape, for example. In such a case, the rotation blocking projection that blocks the rotation of the cooling components may be formed by a corner of the body portion.

(5) In the above-described embodiments, the first part 76 and the second part 78 are fixed to each other with the fixing bolt 94. However, the fixing method is not limited, and it is possible to use bonding, welding, locking using projections and recesses, or the like.

### LIST OF REFERENCE NUMERALS

10, 10a, 10b Circuit assembly
12 Power supply
14 Load
16 Relay (heat generating component)
18 Pre-charge resistor
20 Pre-charge relay
22 Pre-charge circuit
24 Lower case
26 Upper case
28 Base member
30a, 30b Connection portion
32, 34 Bus bar
32a, 34a First connection portion
32b, 34b Second connection portion
36 Lower engaging portion
38 Relay fixing portion
40 Bolt insertion portion
42 Upper wall
44 Peripheral wall
46 Upper engaging portion
48 Accommodating recess
50 Placement surface
52 Partition wall portion
54 Through hole
56 Pre-charge resistor attachment portion
58 Pre-charge relay attachment portion
60 Relay body
62 Partition plate portion
63 Leg portion
64 Fixing bolt
66, 68 Bolt insertion hole
70 Cooling component
70a First cooling component
70b Second cooling component
72 Annular cylinder body
72a First annular cylinder body
72b Second annular cylinder body
74 Inner hole (fastening component insertion hole)
74a First inner hole
74b Second inner hole
76 First part
78 Second part
79a Attachment surface (of first part to second part)
79b Attachment surface (of second part to first part)
80a First bottom wall portion
80b Second bottom wall portion
82 Protrusion (rotation blocking projection)
83 Bolt opening
84 Protruding portion (rotation blocking projection)
85 Arc-shaped recess (first flow passageway forming portion)
86a First inner cylinder portion
86b Second inner cylinder portion
88 Protrusion (rotation blocking projection)
90 Bolt hole
92 Arc-shaped recess (second flow passageway forming portion)
94 Fixing bolt
95 Coolant flow path
96 O-ring (sealing member)
96a Outer circumferential O-ring
96b Inner circumferential O-ring
98 Tube
100 Through hole
102 Through hole (flow inlet, flow outlet)
104 Tube (coolant supply path, coolant discharge path)
108 Fixing bolt
120 Circuit assembly
122 Bolt
130 Circuit assembly
132 Cooling component
140 Circuit assembly

1. A circuit assembly comprising:
a heat generating component that generates heat when energized;
a conductive member configured to be connected to a connection portion of the heat generating component; and
a cooling component configured to allow a coolant to flow therethrough and is in thermal contact with the conductive member.

2. The circuit assembly according to claim 1,
wherein the cooling component is fastened to the connection portion of the heat generating component via the conductive member.

3. The circuit assembly according to claim 1,
wherein the cooling component includes a coolant flow path including a flow inlet and a flow outlet for the coolant, and is configured to allow an external coolant supply path and an external coolant discharge path to be connected to the flow inlet and the flow outlet.

4. The circuit assembly according to claim 3,
wherein the cooling component includes an annular cylinder body, and an inner hole of the annular cylinder body serves as a fastening component insertion hole,
the annular cylinder body includes an annular first part and an annular second part that are configured to be attached to each other in an axial direction thereof, the first part includes a recessed first flow passageway forming portion that is open to an attachment surface to the second part, and the second part includes a recessed second flow passageway forming portion that is open to an attachment surface to the first part, and
as a result of the first part and the second part being attached and fixed to each other in a state in which the attachment surfaces are in close contact with each other via a sealing member, the coolant flow path defined by the first flow passageway forming portion and the second flow passageway forming portion is formed inside the annular cylinder body.

5. The circuit assembly according to claim 4,
wherein one of the first part and the second part that comes into contact with the conductive member is formed of a material having higher thermal conductivity than a material that forms the other of the first part and the second part.

6. The circuit assembly according to claim 1,
wherein the cooling component is fixed to the conductive member using a bolt so as to be in contact with the conductive member, and the cooling component includes a rotation blocking projection that abuts against another member to block rotation of the cooling component.
